(19) United States
(12) Patent Application Publication
(10) Pub. No.: US 2021/0035735 A1
(43) Pub. Date: Feb. 4, 2021

(54) COIL AND A MANUFACTURING METHOD THEREOF

(71) Applicant: ACEINNA Transducer Systems Co., Ltd., Wuxi (CN)

(72) Inventors: Leyue Jiang, Wuxi (CN); Dalai Li, Wuxi (CN); Alexander Dribinsky, Naperville, IL (US)

(73) Assignee: ACEINNA Transducer Systems Co., Ltd., Wuxi (CN)

(21) Appl. No.: 16/935,214

(22) Filed: Jul. 22, 2020

(30) Foreign Application Priority Data
Jul. 30, 2019 (CN) 201910696675.7

(51) Int. Cl. H01F 41/04; H01F 41/02; H01F 27/28

(52) U.S. Cl. CPC H01F 41/041; H01F 2027/2809; H01F 27/2804; H01F 41/0206

(57) ABSTRACT

The present invention relates to a coil and a manufacturing method thereof. The method includes: depositing a first metal layer on a first surface of a wafer and patterning the first metal layer to obtain a first patterned metal layer on the first surface; etching a plurality of through holes on a second surface of the wafer to the first surface of the wafer, and depositing a second metal layer on the second surface of the etched wafer and patterning the second metal layer to obtain a plurality of through hole metals and a second patterned metal layer on the second surface; and, dicing the wafer to obtain a plurality of independent coils. Each coil comprises the first patterned metal layer, the through hole metals and the second patterned metal layer. The first patterned metal layer is coupled with the second patterned metal layer through the through hole metals. Thus, high-precision coils can be efficiently manufactured in batches and at low costs through a wafer level process. The coil may be used for generating or inducing an electromagnetic field.

### RELATED APPLICATION

This application claims the priority from CN Application having serial number 201910696675.7, filed on Jul. 30, 2019, which are incorporated herein by reference for all purposes.

### FIELD OF THE INVENTION

The present invention relates to the field of micro-devices, and in particular, to a coil and a manufacturing method thereof.

### BACKGROUND TECHNIQUE

A coil is one of electronic elements widely used in inductor devices. How to efficiently fabricate high-precision coils in batches and at low costs has always been a difficult issue.

Therefore, it is necessary to provide a solution to resolve the problem.

### SUMMARY OF THE INVENTION

The present invention is intended to provide a coil and a manufacturing method thereof, which can efficiently manufacture high-precision coils in batches and at low costs through a wafer level process.

To resolve the foregoing technical problems, a method for manufacturing coils provided according to an aspect of the present invention, includes: depositing a first metal layer on a first surface of a wafer and patterning the first metal layer to obtain a first patterned metal layer on the first surface; etching a plurality of through holes on a second surface of the wafer to the first surface of the wafer, and depositing a second metal layer on the second surface of the etched wafer and patterning the second metal layer to obtain a plurality of through hole metals and a second patterned metal layer on the second surface; and dicing the wafer to obtain a plurality of independent coils. Each coil comprises the first patterned metal layer, the through hole metals and the second patterned metal layer. The first patterned metal layer is coupled with the second patterned metal layer through the through hole metals.

According to another aspect of the present invention, a coil manufactured based on a wafer level process are provided, including: a base body being formed by dicing a wafer; a first patterned metal layer formed on a first surface of the base body; a second patterned metal layer formed on a second surface of the base body; and two rows of through hole metals extending from the first surface of the base body to the second surface of the base body, and each row of through hole metals comprising one or more through hole metals spaced apart from each other. The first patterned metal layer is coupled with the second patterned metal layer through the through hole metals, and the first patterned metal layer is obtained by depositing a first metal layer on a first surface of the wafer and patterning the first metal layer. The through hole metal and the second patterned metal layer are obtained by etching a plurality of through holes on a second surface of the wafer to the first surface of the wafer, and depositing a second metal layer on the second surface of the etched wafer and patterning the second metal layer.

Compared with the prior art, high-precision coils according to one embodiment of the present invention can be efficiently fabricated in batches and at low costs through a wafer level process. The coil may be used for generating or inducing an electromagnetic field.

### BRIEF DESCRIPTION OF THE DRAWINGS

The drawings described herein are provided to further understand the present application, and are intended to be a part of this application. In the drawing:

FIG. 1 is a schematic diagram illustrating a process of a method for manufacturing coils according to a first embodiment of the present invention;

FIG. 2 is a schematic top view of a coil manufactured based on the method shown in FIG. 1;

FIG. 3 is a schematic cross-sectional view of the coil shown in FIG. 2 taken along a section line A-A;

FIG. 4 is a schematic diagram illustrating a process of a method for manufacturing coils according to a second embodiment of the present invention;

FIG. 5 is a schematic top view of a coil manufactured based on the method shown in FIG. 4; and

FIG. 6 is a schematic cross-sectional view of the coil shown in FIG. 5 taken along a section line B-B.

### DETAILED DESCRIPTION OF THE INVENTION

In order to make the schemes and advantages of the embodiments of the present invention clearer, the exemplary embodiments of the present invention are further described in detail with reference to the accompanying drawings. Obviously, the described embodiments are only part of the embodiments of the present invention, and not all exhaustive embodiments. It should be noted that the embodiments of the present invention and the features of the embodiments may be combined with each other in case of no conflict.

The present invention provides a method for manufacturing coils, which can be used for efficiently manufacturing high-precision coils in batches and at low costs through a wafer level process. The coil may be used for generating or inducing an electromagnetic field, and may be applied to an inductor device, a fluxgate sensor, an electromagnetic induction coil, a radio frequency transceiver and/or an integrated circuit inductor.

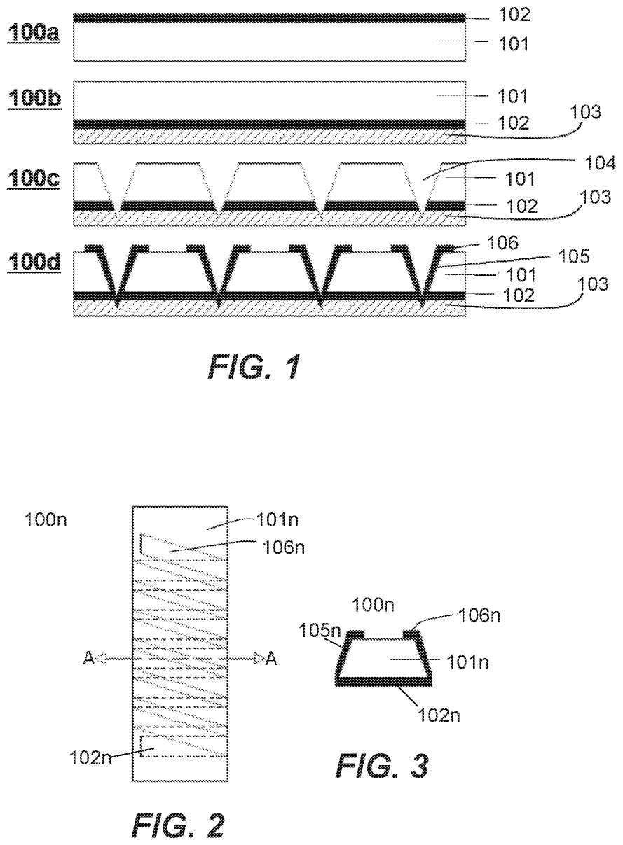

FIG. 1 is a schematic diagram illustrating a process of a method for manufacturing coils according to a first embodiment of the present invention. The coil is a chip-level coil, which may be manufactured to a very small size and may be integrated into a chip. Referring to FIG. 1, the method for manufacturing coils according to the first embodiment of the present invention includes the following operations.

At operation 1, as shown in 100a in FIG. 1, a first metal layer is deposited on a first surface of a wafer 101 and patterned to obtain a first patterned metal 102 on the first surface.

At operation 2, as shown in 100b in FIG. 1, the wafer 101 is turned over for back etching, and a die attach film (DAF) 103 is attached to the first patterned metal 102.

At operation 3, as shown in 100c in FIG. 1, a plurality of through holes 104 is etched on a second surface of the wafer 101 by using a back V-groove process. In this embodiment, the through holes may be V-grooves, and the through holes 104 extend from the second surface to the first surface.

At operation 4, as shown in 100d in FIG. 1, a second metal layer is deposited on the second surface of the etched wafer 101 and patterned to obtain a plurality of through hole metals 105 and a second patterned metal layer 106.

At operation 5, as shown in FIG. 2 and FIG. 3, the wafer 101 is diced to obtain a plurality of independent coils 100n.

FIG. 2 is a schematic top view of a coil manufactured based on the method shown in FIG. 1, and FIG. 3 is a schematic cross-sectional view of the coil shown in FIG. 2 taken along a section line A-A. As shown in FIG. 2 and FIG. 3, each coil 100n includes a base body 101n, a first patterned metal layer 102n on a first surface of the base body 101n, a second patterned metal layer 106n on a second surface of the base body 101n, and two rows of through hole metals 105n extending from the first surface of the base body 101n to the second surface of the base body 101n. Each row of through hole metals 105n includes one or more through hole metals 105n spaced apart from each other, and the first patterned metal layer 102n is coupled with the second patterned metal layer 106n through the through hole metals 105n. The first patterned metal layer 102n, the through hole metal 105n and the second patterned metal layer 106n are coupled to form a spiral coil surrounding the base body 101n, and the base body 101n is formed by dicing the wafer 101. The number of turns of the spiral coil may be one or more, which may be designed as required.

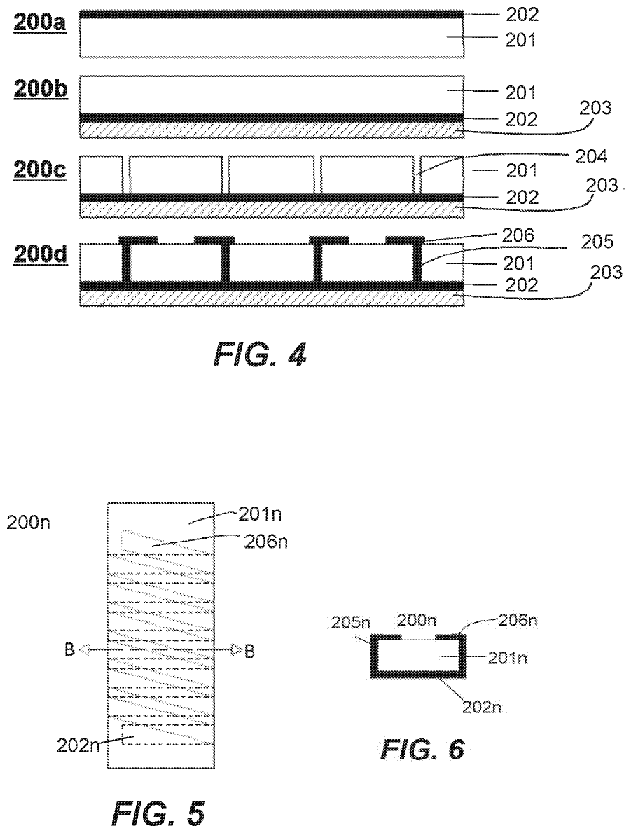

FIG. 4 is a schematic diagram illustrating a process of a method for manufacturing coils in a second embodiment according to the present invention. Referring to FIG. 4, the method for manufacturing coils according to the second embodiment of the present invention includes the following operations.

At operation 1, as shown in 200a in FIG. 4, a first metal layer is deposited on a first surface of a wafer 201 and patterned to obtain a first patterned metal layer 202.

At operation 2, as shown in 200b in FIG. 4, the wafer 201 is turned over for back etching, and a DAF 203 is attached to the first patterned metal layer 202.

At operation 3, as shown in 200c in FIG. 4, a plurality of through holes 204 is etched on a second surface of the wafer 201 by using a through silicon via (TSV) process. In this embodiment, the through holes are deep through holes, and the through holes 204 extend from the second surface to the first surface.

At operation 4, as shown in 200d in FIG. 4, a second metal layer is deposited on the second surface of the etched wafer 201 and patterned to obtain a plurality of through hole metals 205 and a second patterned metal layer 206.

At operation 5, as shown in FIG. 5 and FIG. 6, the wafer 201 is diced to obtain a plurality of independent coils 200n.

FIG. 5 is a schematic top view of a coil manufactured based on the method shown in FIG. 4, and FIG. 6 is a schematic cross-sectional view of the coil shown in FIG. 5 taken along a section line B-B. As shown in FIG. 5 and FIG. 6, each coil 200n includes a base body 201n, a first patterned metal layer 202n on a first surface of the base body 201n, a second patterned metal layer 206n on a second surface of the base body 201n, and two rows of through hole metals 205n extending from the first surface of the base body 201n to the second surface of the base body 201n. Each row of through hole metals 205n includes one or more through hole metals 205n spaced apart from each other, and the first patterned metal layer 202n is coupled with the second patterned metal layer 206n through the through hole metals 205n. The first patterned metal layer 202n, the through hole metal 205n and the second patterned metal layer 206n are coupled to form a spiral coil surrounding the base body 201n, and the base body 201n is one of a plurality of base bodies formed by dicing the wafer 201.

In an alternative embodiment, the operation of turning over the wafer 201 may be performed selectively, as long as it can be ensured that the subsequent operations 3 and 4 are performed. The operation of attaching the DAF to the first patterned metal layer may be changed to be performed after the operation 4, as long as the attachment of the DAF is completed before the operation 5. In addition, the operation of attaching the DAF to the first patterned metal layer may be changed to attach the DAF to the second patterned metal layer.

For ease of description, the operations 1, 2, 3, and 4 are described in order, but the order of the operations may be adjusted according to requirement. For example, the operations 3 and 4 are performed first, and then the operation 1 is performed.

In another alternative embodiment, the operation of patterning the first metal layer may be performed immediately after the first metal layer is deposited, or may be performed in a subsequent process, for example, may be performed after the operations 2, 3, or 4. The operation of patterning the second metal layer may be performed immediately after the second metal layer is deposited, or may be performed in a subsequent process.

In the foregoing descriptions, “first surface” may also be replaced with “front surface”, “second surface” may also be replaced with “back surface”. The term “spiral” in this specification may be a standard spiral shape, but may also refer to a non-standard spiral shape, for example, an irregular spiral shape shown in FIG. 2 and FIG. 5.

In the foregoing descriptions, the through holes may refer to through holes shown in 200c in FIG. 4, or V-grooves shown in 100c in FIG. 1, or through holes of other shapes that can run through the wafer.

By means of the method for manufacturing coils of the present invention, high-precision coils can be efficiently fabricated in batches and at low costs through a wafer level process. The coil may be used for generating or inducing an electromagnetic field, and may be applied to an inductor device, a fluxgate sensor, an electromagnetic induction coil, a radio frequency transceiver and/or an integrated circuit inductor.

In this specification, the terms “include”, “comprise”, or their any other variant is intended to cover a non-exclusive inclusion, not only including those listed elements but also including other elements that are not expressly listed.

In this specification, directional terms such as front, back, up, and down are defined according to the positions of parts in the accompanying drawings and relative positions of the parts, and are used only for clearly and conveniently describing the technical solutions. It should be understood that the use of the directional terms should not limit the protection scope claimed by the present application.

Moreover, in a case that no conflict occurs, the embodiments in this specification and the features in the embodiments may be combined.

Obviously, a person skilled in the art may make various changes and variations to the application without departing from the spirit and scope of the application. Thus, if these modifications and variations of this application fall within the scope of the claims and their equivalent technologies, the application is also intended to include these changes and variations.

What is claimed is:

1. A method for manufacturing coils, comprising:
depositing a first metal layer on a first surface of a wafer and patterning the first metal layer to obtain a first patterned metal layer on the first surface;
etching a plurality of through holes on a second surface of the wafer to the first surface of the wafer, and depositing a second metal layer on the second surface of the etched wafer and patterning the second metal layer to obtain a plurality of through hole metals and a second patterned metal layer on the second surface; and
dicing the wafer to obtain a plurality of independent coils,
wherein each coil comprises the first patterned metal layer, the through hole metals and the second patterned metal layer, and
wherein the first patterned metal layer is coupled with the second patterned metal layer through the through hole metals.

2. The method according to claim 1, wherein
the through holes are etched on the second surface of the wafer by using a V-groove process; or
the through holes are etched on the second surface of the wafer by using a through silicon via process.

3. The method according to claim 1, wherein before the dicing the wafer, the method further comprises:
attaching a die attach film to the first patterned metal layer or the second patterned metal layer.

4. The method according to claim 1, wherein the first patterned metal layer, the through hole metals and the second patterned metal layer of each coil are coupled to form a spiral coil surrounding a base body formed by dicing the wafer.

5. A coil manufactured based on a wafer level process, comprising:
a base body being formed by dicing a wafer;
a first patterned metal layer formed on a first surface of the base body;
a second patterned metal layer formed on a second surface of the base body; and
two rows of through hole metals extending from the first surface of the base body to the second surface of the base body, and each row of through hole metals comprising one or more through hole metals spaced apart from each other;
wherein the first patterned metal layer is coupled with the second patterned metal layer through the through hole metals, and the first patterned metal layer is obtained by depositing a first metal layer on a first surface of the wafer and patterning the first metal layer, and
wherein the through hole metal and the second patterned metal layer are obtained by etching a plurality of through holes on a second surface of the wafer to the first surface of the wafer, and depositing a second metal layer on the second surface of the etched wafer and patterning the second metal layer.

6. The coil according to claim 5, wherein the first patterned metal layer, the through hole metals and the second patterned metal layer are coupled to form a spiral coil surrounding the base body.
